(19) United States
(12) Patent Application Publication
(10) Pub. No.: US 2018/0190610 A1
(43) Pub. Date: Jul. 5, 2018

(54) METHOD FOR JOINING AT LEAST TWO COMPONENTS

(71) Applicant: OSRAM Opto Semiconductors GmbH, Regensburg (DE)

(72) Inventor: Mathias WENDT, Hausen (DE)

(21) Appl. No.: 15/740,785

(22) PCT Filed: Jun. 22, 2016
(86) PCT No.: PCT/EP2016/064454

§ 371 Date: Dec. 28, 2017

(30) Foreign Application Priority Data
Jul. 8, 2015 (DE) 10 2015 111 040.7

(51) Int. Cl. H01L 23/00; C04B 37/00; C03C 27/08; H01L 33/08; H01L 33/62

(52) U.S. Cl. CPC H01L 24/29; C04B 37/003; C03C 27/08; H01L 33/08; H01L 33/62; C23C 14/086; C04B 2237/343; C04B 2237/368; C04B 2237/06; C04B 2237/60; H01L 24/83

(57) ABSTRACT

The invention relates to a method for connecting at least two components (1, 2), comprising the following steps: A) providing at least a first component (1) and a second component (2), B) applying at least one donor layer (3) to the first and/or the second component (1, 2), wherein the donor layer (3) is enriched with oxygen (31), C) applying a metal layer (4) to the donor layer (3), the first or the second component (1, 2), D) heating at least the metal layer (4) to a first temperature (T1) such that the metal layer (4) is melted and the first component (1) and the second component (2) are connected to one another, and E) heating the arrangement to a second temperature (T2) such that the oxygen (31) passes from the donor layer (3) into the metal layer (4) and the metal layer (4) is converted to form a stable metal oxide layer (5), wherein the metal oxide layer (5) has a higher melting temperature than the metal layer (4), wherein at least the donor layer (3) and the metal oxide layer (5) connect the first component (1) and the second component (2) to one another.

The invention relates to a method for connecting at least two components.

To date, components have been connected to one another using connecting techniques such as, for example, silicon dioxide/silicon dioxide direct bonding, adhesive bonding and metallic bonding.

It is an object of the invention to provide a method for connecting at least two components which produces a stable connection between the two components.

The object is achieved by a method for connecting at least two components according to independent patent claim 1. Advantageous configurations and developments of the invention are the subject matter of the dependent claims.

In at least one embodiment, the method for connecting at least two components comprises the following steps:

A) providing at least a first component and a second component,
B) applying at least one donor layer to the first and/or the second component, wherein the donor layer is enriched with oxygen,
C) applying a metal layer to the donor layer, the first and/or the second component,
D) heating at least the metal layer to a first temperature such that the metal layer is melted and the first component and the second component are connected to one another, and
E) heating the arrangement to a second temperature such that the oxygen passes from the donor layer into the metal layer and the metal layer is converted to form a stable metal oxide layer, wherein the metal oxide layer has a higher melting temperature than the metal layer, wherein at least the donor layer and the metal oxide layer connect the first component and the second component to one another.

In particular, the method is carried out in the alphabetical sequence A) to E). As an alternative or in addition, further steps may be provided; by way of example, before step B), the oxygen can be introduced into the donor layer by means of an implantation method to enrich the oxygen in the donor layer.

According to at least one embodiment, the method provides a first and a second component in step A).

The first component and/or the second component can be selected from a various number of materials and elements. By way of example, the first and/or second component can each be selected from a group consisting of sapphire, silicon nitride, a semiconductor material, a ceramic material, a metal and glass.

As an alternative or in addition, the first and/or the second component may also be a pipe and/or a tube. In particular, the pipe is a vacuum pipe.

By way of example, one of the two components may be a semiconductor or ceramic wafer, for example a shaped material composed of sapphire, silicone, germanium, silicon nitride, aluminium oxide, a luminescent ceramic, such as for example YAG. Furthermore, it is possible that at least one component is formed as a printed circuit board (PCB), as a metallic leadframe or as a different type of connection carrier. Furthermore, at least one of the components may comprise, for example, an electronic chip, an optoelectronic chip, a light-emitting diode, a laser chip, a photodetector chip or a wafer or have a plurality of such chips. In particular, the second component and/or the first component comprises a light-emitting diode, LED for short. In particular, the second component comprises the light-emitting diode and the first component comprises at least one of the aforementioned materials.

The component comprising a light-emitting diode is preferably designed to emit blue light, red light, green light or white light.

The light-emitting diode comprises at least one optoelectronic semiconductor chip. The optoelectronic semiconductor chip may comprise a semiconductor layer sequence. The semiconductor layer sequence of the semiconductor chip is preferably based on a III-V compound semiconductor material. The semiconductor material is preferably a nitride compound semiconductor material, such as AlₙIn₁₋ₙ₋ₘGaₘN, or else a phosphide compound semiconductor material, such as AlₙIn₁₋ₙ₋ₘGaₘP, it being applicable in each case that 0≤n≤1, 0≤m≤1 and n+m≤1. Similarly, the semiconductor material may be AlₓGa₁₋ₓAs, where 0≤x≤1. In this case, the semiconductor layer sequence may comprise dopants and additional constituents. For the sake of simplicity, however, only the essential constituents of the crystal lattice of the semiconductor layer sequence are specified, i.e. Al, As, Ga, In, N or P, even if these can be replaced and/or supplemented in part by small quantities of further substances.

The semiconductor layer sequence contains an active layer with at least one pn junction and/or with one or with a plurality of quantum well structures. During operation of the LED or of the semiconductor chip, an electromagnetic radiation is generated in the active layer. A wavelength or a wavelength maximum of the radiation preferably lies in the ultraviolet and/or visible and/or infrared spectral range, in particular at wavelengths of between 420 and 800 nm inclusive, for example between 440 and 480 nm inclusive.

According to at least one embodiment, the method comprises step B), applying at least one donor layer to the first and/or the second component. In particular, the donor layer is a layer enriched with oxygen.

According to at least one embodiment, the donor layer comprises or consists of an oxide of at least one metal. In particular, the donor layer comprises or consists of indium tin oxide, indium oxide, zinc oxide and/or tin oxide. In particular, the indium tin oxide, indium oxide, zinc oxide or tin oxide is enriched with oxygen.

Here and hereinbelow, the fact that the donor layer is enriched with oxygen means that the donor layer has a superstoichiometric proportion of oxygen. The oxygen can be bound covalently to the material of the donor layer in the donor layer. As an alternative or in addition, the oxygen can be incorporated in the donor layer, in particular in the interstices of the host lattice of the donor layer. In other words, the oxygen does not thereby bond covalently to the donor layer.

According to at least one embodiment, the method comprises step C), applying a metal layer to the donor layer. As an alternative or in addition, the metal layer is applied to the first and/or the second component.

In particular, the donor layer comprises metal oxides, such as for example zinc oxide, tin oxide, cadmium oxide, titanium oxide, indium oxide or mixed metal oxides, such as indium tin oxide (ITO). The term “metal oxides” encompasses both binary metal-oxygen compounds, such as for example ZnO, SnO₂ or In₂O₃, and ternary metal-oxygen compounds, such as for example Zn₂SnO₄, CdSnO₃, ZnSnO₃, MgIn₂O₄, GaInO₃, Zn₂In₂O₅ or In₄Sn₃O₁₂ or mixtures of different oxides. In this case, the metal oxides may not necessarily have a stoichiometric composition. In particular, the donor layer is formed from indium tin oxide (ITO).

According to at least one embodiment, the metal layer comprises indium, tin, zinc or a combination of indium and tin.

According to at least one embodiment, the method comprises a step D), heating at least one metal layer to a first temperature T1 such that the metal layer is melted and the first component and the second component are connected to one another. In other words, the first temperature is increased to such an extent that the melting temperature of the metal or of the mixture of the metals of the metal layer is exceeded, and therefore the metals of the metal layer melt. By way of example, indium has a melting temperature of 156.6° C. Tin has a melting temperature of 231.9° C. The metal layer can also comprise or consist of a plurality of metals. In particular, the metal layer comprises a combination of indium and tin. In particular, indium and tin form an eutectic mixture. A mixture of indium with 52% by weight and tin with 48% by weight has a melting temperature of 117° C. to 118° C. Through the melting of the metal layer, the metal layer behaves like a metallic solder material.

In particular, the metal layer exhibits a ductile behaviour. The metal layer connects the first and the second component to one another. By way of example, the connection may be a mechanical connection between the first component and the second component. Furthermore, the first component and the second component can also be connected electrically via the metal layer. In particular, the metal layer and the donor layer or the metal oxide layer and the donor layer form a connecting element which connects the first component to the second component. In particular, the connecting element is arranged in direct mechanical and/or electrical contact with the first component and also with the second component.

According to at least one embodiment, the method comprises a step E), heating the arrangement to a second temperature such that the oxygen passes from the donor layer into the metal layer and the metal layer is converted to form a stable metal oxide layer. In particular, the metal oxide layer has a higher melting temperature than the metal layer. In this case, at least the donor layer and the metal oxide layer connect the first component to the second component, or vice versa.

In other words, a stable mechanical connection and if appropriate additionally an electrical connection is produced by the connection of the two components via the donor layer and the metal oxide layer.

According to at least one embodiment, the second temperature in step E) is greater than the first temperature in step D). In particular, the first and the second temperature differ from one another by at least the factor 1.5; 1.8; 1.9; 2; 2.5 or 3. By heating the arrangement, which in particular comprises the metal layer, the first component, the second component and the donor layer, to a second temperature, the excess oxygen passes from the donor layer into the metal layer. The metal layer undergoes oxidation or autooxidation to form the metal oxide layer. The metal layer is converted into a solid metal oxide layer. In particular, the metal oxide layer is mechanically stable. The metal oxide layer has a higher melting temperature or a higher remelting temperature than the metal layer. The metal oxide layer is produced from the metal layer and the oxygen present in the donor layer. It is therefore not necessary to supply other external reaction partners to produce a stable connection.

According to at least one embodiment, the metal layer comprises indium, zinc, tin or a combination of indium and tin. In the case of indium as the metal layer, indium oxide is formed as the metal oxide layer. In the case of tin as the metal layer, tin oxide is formed as the metal oxide layer. In the case of zinc as the metal layer, zinc oxide is formed as the metal oxide layer. In the case of a mixture of indium and tin as the metal layer, indium tin oxide is formed as the metal oxide layer.

As an alternative or in addition, the donor layer may be composed of indium oxide, tin oxide or indium tin oxide. In particular, the donor layer is formed from indium tin oxide. Indium tin oxide has the advantage that it is transparent and electrically conductive. There is thereby a low absorption of light in the visible wavelength range. In addition, there is sufficient thermal and mechanical stability for producing the components, in particular optoelectronic semiconductor components.

The metal oxide layer has a higher melting point compared to the metal layer and if appropriate is transparent. By way of example, the metal layer composed of indium has a melting point of 156.9° C. and the metal oxide layer composed of indium oxide (In₂O₃) has a higher melting point of 1910° C. By way of example, the metal layer composed of tin has a melting point of 231.9° C. and the metal oxide layer composed of tin oxide has a higher melting point of 1630° C. By way of example, the metal layer composed of indium and tin has a melting point of 118° C. and the metal oxide layer composed of indium tin oxide (ITO) has a higher melting point of approximately 1900° C.

The method is similar to the bonding process often used in the semiconductor industry, in which the connection is formed by an isothermal solidification reaction. The significant difference, however, is that the metal oxide layer is not formed by mixing and reacting a plurality of alloy elements, but rather by oxidation of the metal layer with the oxygen from the donor layer. This produces a connecting element with a sufficiently high melting point which is suitable, for example, for manufacturing optoelectronic semiconductor components.

The inventor has recognized that, with the joining method proposed here, in particular metallic, non-transparent connecting elements can be converted by oxidation into a ceramic and possibly also conductive and transparent layer. This connecting element, which in particular comprises the donor layer and the metal oxide layer, has a high connecting force or adhesive force in relation to the first and second component. The connecting element may have good optical properties, such as a high transparency of >80% or 90% for visible light. Furthermore, the connecting element may additionally have electrical properties, such as a high electrical conductivity.

According to at least one embodiment, the donor layer and the metal oxide layer comprise the same metal oxides after step D). In addition, the donor layer and the metal oxide layer may differ merely in terms of their proportion of oxygen.

According to at least one embodiment, the donor layer and the metal layer are applied by sputtering. As an alternative or in addition, the metal oxide layer can be produced by oxidation of the metal layer. Alternatively, thermal evaporation may be used instead of sputtering.

According to at least one embodiment, the donor layer is produced by means of sputtering, in step B), of at least one metal and of oxygen to form a metal oxide. The metal layer is produced by sputtering, for example in the same system, of at least one metal. In particular, the metal of the metal layer corresponds to the metal of the metal oxide of the donor layer.

According to at least one embodiment, the oxygen is introduced in step B). In particular, a continuous or discontinuous oxygen stream is effected into the donor layer at a speed k1 and/or with a proportion n1 to introduce the oxygen. In particular, the oxygen in step C) has a speed rate k2<k1 and/or a proportion n2<n1 such that the metal layer is produced. In other words, a metal, such as tin, and oxygen are applied as tin oxide, for example, for producing the donor layer. A constant oxygen stream can flow, such that the tin oxide is formed. As the method progresses, the proportion of oxygen can be reduced, such that tin is deposited in metallic form and no tin oxide is formed. The metal layer is thus formed. Then, in method step D), the metal layer can be melted and the two components can be connected. In a subsequent heating step at a second temperature, the oxygen can then pass from the oxygen-rich donor layer into the metal layer, and thereby form a metal oxide, such as tin oxide, as the metal oxide layer from the metal of the metal layer, such as tin, for example. In other words, no further reaction partners apart from oxygen are required here to form a stable connecting element.

According to at least one embodiment, the metal layer and the donor layer each have a layer thickness of 10 nm to 200 nm, in particular of between 40 nm and 120 nm, for example 60 nm. The metal oxide layer may have a layer thickness of 10 nm to 200 nm, in particular of between 40 nm and 120 nm, for example 60 nm.

According to at least one embodiment, the first temperature is selected from a temperature range of 25° C. to 250° C., in particular of between 120° C. and 240° C., for example 170° C. The second temperature has in particular a higher temperature than the first temperature. In particular, the second temperature is higher than 200° C., for example 230° C.

According to at least one embodiment, the oxygen of the donor layer is introduced into the donor layer after step B) by means of an ion implantation method. The ion implantation method is known to those skilled in the art and is therefore not explained in more detail here.

Alternatively, the oxygen of the donor layer can be introduced into the donor layer during step B) by means of an oxygen stream.

The oxygen can be incorporated in the donor layer in a superstoichiometric ratio in both methods. In particular, the donor layer is formed from indium tin oxide, and therefore indium tin oxide with a superstoichiometric proportion of oxygen is present after the introduction of oxygen. The oxygen is incorporated in particular in the interstices or pores of the host crystal.

According to at least one embodiment, the first and the second component are connected under pressure. In particular, the pressure is at least 1.8 bar, for example 2 bar.

With the method proposed here, it is possible, for example, for optoelectronic semiconductor components to be connected directly to one another. The method can replace direct bonding, for example. The significant challenge in direct bonding is represented by the high demands placed on the surfaces. These surfaces have to be largely free of particles and very smooth. In addition, the components may exhibit only a very small degree of deflection and a relatively low total thickness variation (TTV). Thus, by way of example, a particle having a size of 10 nm leads to a cavity (void) having a size of approximately 100 μm. In the method proposed here, particles having a size of 10 nm can be pressed into and embedded in the metal layer which is liquid during the connection, without cavities being produced. This affords major advantages with respect to the low demands made on the surface quality of the components, and this can lead to higher yields and can reduce the number of process steps.

The invention furthermore specifies a structural element. The structural element comprises in particular at least the two components, the donor layer and the metal oxide layer. In particular, the structural element is produced from the above-described method for connecting at least two components. That is to say that all of the features disclosed for the method are also disclosed for the structural element, and vice versa.

According to at least one embodiment, the structural element comprises at least two components, the first and second components. A donor layer and a metal oxide layer are arranged between the two components. The metal oxide layer is produced by oxidation of a metal layer. The donor layer is enriched with oxygen. The oxygen is introduced into the donor layer for the oxidation of the metal layer to produce the metal oxide layer. In particular, the donor layer and the metal oxide layer comprise the same materials. The donor layer and the metal layer are preferably formed from indium tin oxide, tin oxide or indium oxide.

According to at least one embodiment, the structural element comprises an optoelectronic semiconductor component as the first and/or second component. In particular, the optoelectronic semiconductor component is at least a III-V compound semiconductor material and comprises a pn junction.

According to at least one embodiment, the structural element comprises at least two or precisely two semiconductor layer sequences which are each designed to emit radiation in the same or a different wavelength range. In particular, during operation of the structural element, the at least two semiconductor layer sequences emit different radiation selected from the blue, red and green wavelength range. The semiconductor layer sequence comprises at least one p-doped semiconductor layer, at least one n-doped semiconductor layer and an active layer with a pn junction. At least one donor layer, in particular one or two donor layers, and a metal oxide layer are arranged between the at least two semiconductor layer sequences. In the case of 2 donor layers, one donor layer is arranged directly on, i.e. in direct mechanical contact with, one semiconductor layer sequence, and the other donor layer is arranged directly on, i.e. in direct mechanical contact with, the other semiconductor layer sequence. The metal oxide layer is arranged between the two donor layers and directly adjoins both the first and the second donor layer. In other words, the structural element has the following structure: semiconductor layer sequence—donor layer—metal oxide layer—donor layer—semiconductor layer sequence. The structural element can thus generate radiation of any possible colour.

In addition, it is also possible for more than two semiconductor layer sequences, for example three, four or five, to be present in the structural element. Adjacent semiconductor layer sequences are then separated from one another by two donor layers and a metal oxide layer.

According to at least one embodiment, the two donor layers and the metal oxide layer are each formed from the same material, in particular from a transparent and/or conductive material, such as indium tin oxide.

Further advantages, advantageous embodiments and developments will become apparent from the exemplary embodiments described hereinbelow in conjunction with the figures.

In the figures:

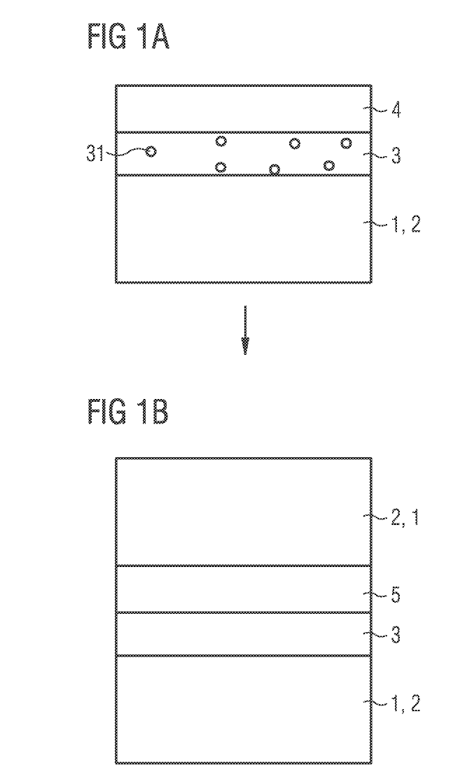

FIGS. 1A to 5C each show a schematic side view of a method for connecting at least two components according to one embodiment.

In the exemplary embodiments and figures, identical elements, similar elements or elements having the same effect may each be provided with the same reference numerals. The elements shown and the size ratios thereof in relation to one another are not to be considered as true to scale. Instead, individual elements such as, for example, layers, components, structural elements and regions may be shown with an exaggerated size for better illustration and/or for better understanding.

FIGS. 1A and 1B show a method for connecting or joining at least two components according to one embodiment. FIG. 1A shows the provision at least of the first component 1 and of the second component 2 (step A)). The donor layer 3 is applied to the first component 1 and/or second component 2 in particular in direct mechanical and/or electrical contact. The donor layer 3 is enriched in particular with oxygen 31. By way of example, the donor layer is formed from indium tin oxide. The oxygen 31 in the indium tin oxide accumulates in particular in the interstices of the crystal lattice of the mixed oxide indium tin oxide (ITO). In particular, a metal layer 4 is arranged directly subsequent to the donor layer 3. The donor layer 3 and the metal layer 4 are applied in particular by sputtering from the same system. In particular, the metal layer comprises a metal which is the same as the metal of the metal oxide or mixed metal oxide of the donor layer 3 (steps B) and C)). This is followed by the heating at least of the metal layer 4 or of the entire arrangement comprising the first and/or second component, the donor layer 3 and the metal layer 4 to a first temperature T1. In particular, the first temperature T1 is so high that the metal layer 4 is melted and connects the first component 1 and the second component 2 to one another. In particular, this is a mechanical and/or electrical connection (step D)). Then, the arrangement can be heated to a second temperature T2, such that the oxygen 31 passes from the donor layer 3 into the metal layer 4. A metal oxide layer 5 is formed from the metal layer 4, which comprises a metal, by oxidation. The metal oxide layer 5 is in particular mechanically stable and/or transparent. In this case, the metal oxide layer 5 has a higher remelting temperature than the metal layer 4. This produces an outstanding connection between the first and the second component 1, 2.

FIG. 1B shows a schematic side view when the two components are connected to one another. In this case, the arrangement comprises a first component 1, followed by a donor layer 3, followed by a metal oxide layer 5, followed by a second component 2. As an alternative, the donor layer 3 may also be arranged subsequent to the second component 2. The metal oxide layer 5 is then arranged subsequent to the donor layer 3 and in turn the first component 1 is arranged subsequent to said metal oxide layer.

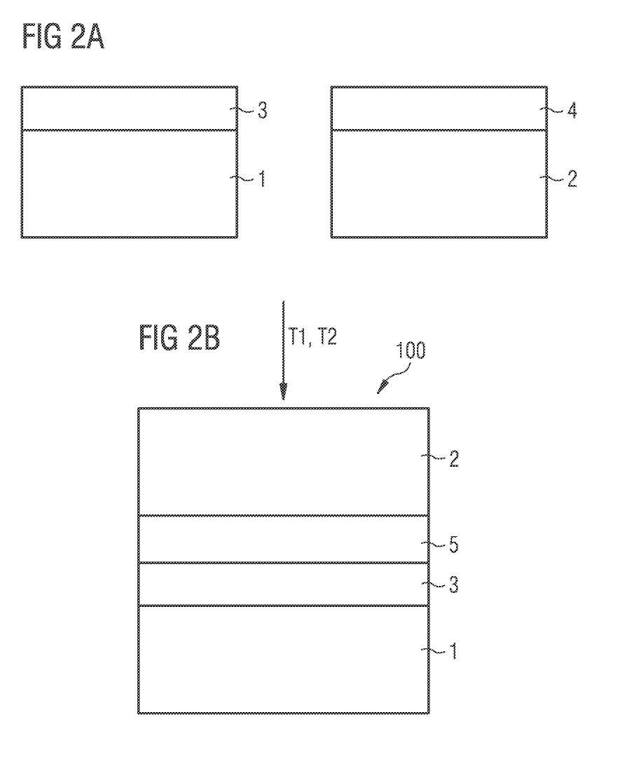

FIGS. 2A and 2B show the connection of at least two components 1, 2 according to one embodiment. The donor layer 3 can be applied to the first component 1. The donor layer 3 is enriched in particular with oxygen 31 (not shown here). The metal layer 4 can be applied to the second component 2. Then, method steps D) and E) can be carried out. This forms a structural element 100 comprising a first component 1, followed by a donor layer 3, followed by a metal oxide layer 5, followed by a second component 2. In other words, the metal layer 4 is converted into the metal oxide layer 5 by oxidation with the oxygen 31 present in the donor layer.

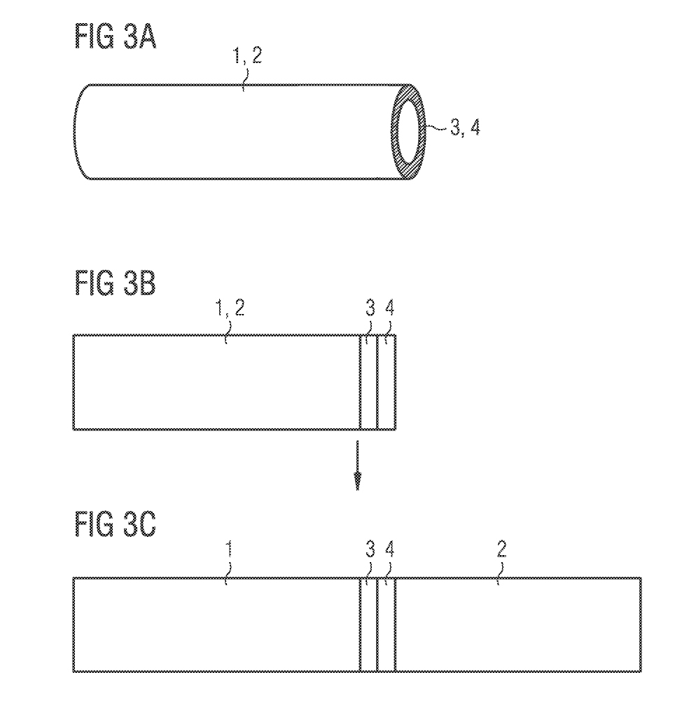

FIGS. 3A to 3B show a method for connecting at least two components 1, 2. FIG. 3A shows a component 1. Alternatively, FIG. 3A shows a second component 2. The components 1, 2 have in particular a tubular shape. In particular, the two components 1, 2 are each a pipe. A donor layer 3 is applied to the cross-sectional areas of the respective component 1, 2. Then, a metal layer 4 can be applied (FIG. 3B). At least two pipes are connected or joined in order to produce a fixed connection between the two pipes (FIG. 3C).

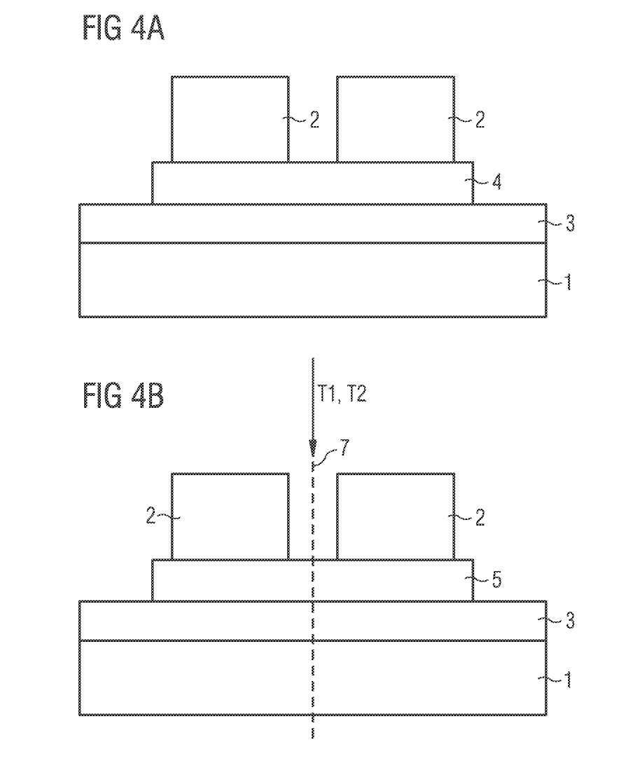

FIGS. 4A and 4B show a method for connecting at least two components 1, 2 according to one embodiment. In particular, the second component 2 comprises an optoelectronic semiconductor component or an LED. FIGS. 4A and 4B differ from FIGS. 1A and 2B in that two second components 2 are applied to a first component 1. As an alternative or in addition, it is also possible for more than two second components 2 to be applied to a first component 1, or vice versa. A donor layer 3 enriched with oxygen 31 can be applied to a first component 1. This is followed by the application of a metal layer 4 and the application of the second components 2. The first and second components 1, 2 are connected to one another in step D), the metal layer 4 being heated in said step to a first temperature T1 such that the melting temperature is exceeded. As a result, the metal layer 4 is present in molten form and can produce a connection between the first component and each second component 2. In a further heating step at a second temperature T2, the metal layer can be converted into a metal oxide layer 5 with the oxygen 31 of the donor layer 3. What results is a connecting element comprising a donor layer 3 and a metal oxide layer 5, which produces a fixed mechanical and/or electrical connection between the two components 1, 2. Then, the second components 2, which are located on a common first component 1, can be singulated 7. This can be effected, for example, by means of sawing or a laser separation method.

It is also possible in particular for III-V semiconductor layers to be arranged on a first and/or second component 1, 2. In particular, the first and/or second component 1, 2 is then formed as a growth substrate. Firstly, a donor layer 3 composed of a metal oxide, for example indium tin oxide, can be applied to the exposed surface of the III-V semiconductor layers.

The donor layer 3 composed of indium tin oxide comprises in particular a superstoichiometric proportion of oxygen. In particular, the donor layer 3 is deposited with a thickness of 60 nm. The donor layer 3 is reactive; i.e., for example, the metal particles, for example indium and tin, react with the oxygen to form a metal oxide, such as indium tin oxide.

The donor layer 3 is applied by sputtering, with oxygen being added to the process gas. In particular, the composition of the target used for sputtering is 90% by weight indium and 10% by weight tin. In a further process, the admixture of oxygen to the process gas is interrupted such that, at least with an increasing thickness of the applied donor layer 3, in particular of the indium tin layer, a decreasing quantity of oxygen is present therein. In particular, sputtering is continued until a metal layer 4, in particular composed of indium and tin, is present on the surface.

The metal layer 4 has in particular a thickness of 4 to 8 nm, for example 5 nm. Then, the first and the second component 1, 2 can be connected to one another, in particular connected. The connection can be carried out in particular at a first temperature T1 of <200° C., for example at 180° C. Proceeding from room temperature, i.e. proceeding from 25° C., the components 1, 2 are heated to the first temperature T1 used for the connection. When the first temperature T1 has been reached, the layers are pressed onto one another in particular with a pressure of >1.8 bar, for example 2 bar. The components 1, 2 can be held in this state for approximately five minutes.

Then, the temperature can be increased further to a second temperature T2, for example to up to 350° C. The two components 1, 2 can be fired at this temperature for one hour. In this process, it is the case in particular that the oxygen 31 diffuses from the donor layer 3 into the metal layer 4, which consists in particular of indium tin, and converts the metal of the metal layer 4 into a metal oxide layer 5.

In particular, the metal oxide layer 5 is ceramic. As an alternative or in addition, the metal oxide layer 5 is optically transparent. As an alternative or in addition, the metal oxide layer 5 is electrically conductive. The metal oxide layer preferably consists of indium tin oxide. The connection between the first and the second component 1, 2 via the donor layer 3 and the metal oxide layer 5 thus has a drastically higher melting point than the metal layer 4 beforehand. In addition, the metal oxide layer 5 can have a transparent form as compared to the metal layer 4.

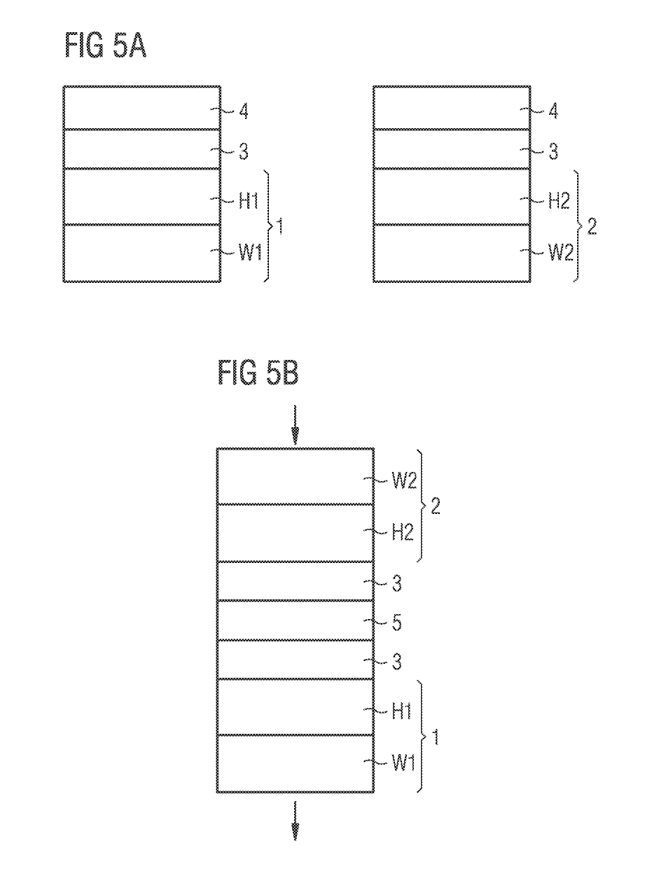

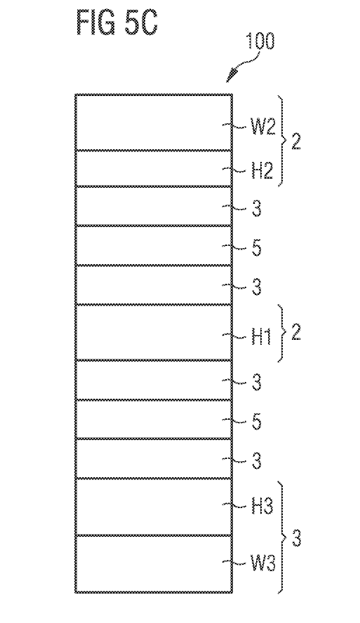

FIGS. 5A to 5C show a method for connecting or joining at least two semiconductor layer sequences H1, H2 according to one embodiment. FIG. 1A shows the provision at least of the first component 1, which comprises a semiconductor layer sequence H1 and a growth substrate W1, for example composed of sapphire. FIG. 1A furthermore shows the provision at least of the second component 2, which comprises a semiconductor layer sequence H2 and a growth substrate W2, for example composed of sapphire. The donor layer 3 is applied both to the first component 1 and to the second component 2 in particular in direct mechanical and/or electrical contact, and then the metal layer 4 is applied in each case.

This is followed by the connection of the two components 1, 2, the metal layer 4 being converted into a metal oxide layer 5 (FIG. 5B). This results in the following layer structure: growth substrate W2—semiconductor layer sequence H2—donor layer 3—metal oxide layer 5—donor layer 3—semiconductor layer sequence H1—growth substrate W1.

The semiconductor layer sequences H1, H2 in particular directly adjoin the respective donor layers 3.

Then, as shown in FIG. 5C, the growth substrate W1 of the first component 1 can be removed, and a donor layer 3 and a metal layer 4 can be applied to the semiconductor layer sequence H1. The steps of FIG. 5A can then be repeated as desired with further components, for example the first, second or a third component 3, this resulting in a structural element which comprises, for example, three semiconductor layer sequences H1, H2, H3, with adjacent semiconductor layer sequences being separated from one another in each case by at least one donor layer 3, in particular two donor layers 3, and a metal oxide layer 5. In particular, the semiconductor layer sequences H1, H2, H3 emit radiation of a differing wavelength, for example radiation from the red, yellow and blue wavelength range, such that the total emission of the structural element 100 can have any wavelength in the visible range, for example white mixed light. In particular, the respective donor layers 3 and the metal oxide layers 5 are formed from indium tin oxide. Absorption losses of the emitted radiation can thereby be reduced.

The exemplary embodiments described in conjunction with the figures and the features thereof can also be combined with one another in accordance with further exemplary embodiments, even if such combinations are not shown explicitly in the figures. Furthermore, the exemplary embodiments described in conjunction with the figures can have additional or alternative features in accordance with the description in the general part.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

This patent application claims the priority of German patent application 10 2015 111 040.7, the content of the disclosure of which is hereby incorporated by reference.

1. Method for connecting at least two components, comprising the following steps:
A) providing at least a first component and a second component,
B) applying at least one donor layer to the first and/or the second component, wherein the donor layer comprises an oxide of at least one metal and is enriched with oxygen, so that the donor layer has a superstoichiometric proportion of oxygen,
C) applying a metal layer to the donor layer, the first or the second component,
D) heating at least the metal layer to a first temperature (T1) such that the metal layer is melted and the first component and the second component are connected to one another, and
E) heating the arrangement to a second temperature (T2) such that the oxygen passes from the donor layer into the metal layer and the metal layer is converted to form a stable metal oxide layer, wherein the metal oxide layer has a higher melting temperature than the metal layer, wherein at least the donor layer and the metal oxide layer connect the first component and the second component to one another.

2. Method according to claim 1,
wherein the donor layer is composed of indium tin oxide, indium oxide, zinc oxide or tin oxide, wherein the indium tin oxide, indium oxide or tin oxide is enriched with oxygen.

3. Method according to claim 1,
wherein the metal layer comprises indium, tin, zinc or a combination of indium and tin,
wherein indium oxide is formed as the metal oxide layer in the case of indium as the metal layer,
wherein tin oxide is formed as the metal oxide layer in the case of tin as the metal layer,
wherein zinc oxide is formed as the metal oxide layer in the case of zinc as the metal layer, and wherein indium tin oxide is formed as the metal oxide layer in the case of a mixture of indium and tin as the metal layer.

4. (canceled)

5. Method according to claim 1,
wherein the donor layer and the metal oxide layer comprise the same metal oxides after step D).

6. Method according to claim 1,
wherein the donor layer and the metal layer are produced by sputtering and the metal oxide layer is produced by oxidation of the metal layer.

7. Method according to claim 6,
wherein the donor layer is produced by means of sputtering, in step B), of at least one metal and of oxygen to form a metal oxide, wherein the metal layer is produced by sputtering, in the same system, of at least one metal, wherein the metal of the metal layer corresponds to the metal of the metal oxide of the donor layer.

8. Method according to claim 7,
wherein, in step B), a continuous oxygen stream is introduced into the donor layer at a speed rate k1 and with a proportion n1 to introduce the oxygen, wherein the oxygen stream in step C) has a speed rate k2<k1 and a proportion n2<n1 such that the metal layer is produced.

9. Method according to claim 1,
wherein the second component comprises a light-emitting diode, and wherein at least the first component is selected from a group consisting of sapphire, silicon nitride, a semiconductor material, a ceramic material, a metal and glass.

10. Method according to claim 1,
wherein the first component and/or the second component is a pipe and/or tube.

11. Method according to claim 1,
wherein the second temperature (T2) in step E) is greater than the first temperature (T1) in step D) and the first and the second temperature (T1, T2) differ from one another by at least the factor 1.5.

12. Method according to claim 1,
wherein the oxygen of the donor layer is introduced into the donor layer after step B) by means of an ion implantation method, or wherein the oxygen of the donor layer is introduced into the donor layer during step B) by means of an oxygen stream.

13. Method according to claim 1,
wherein the first and the second component are connected under a pressure of at least 1.8 bar.

14. Structural element comprising at least two semiconductor layer sequences (H1, H2) which are each designed to emit radiation in the same or a different wavelength range, wherein two donor layers and a metal oxide layer are arranged between the at least two semiconductor layer sequences (H1, H2), wherein one donor layer is arranged directly on one semiconductor layer sequence (H1) and the other donor layer is arranged directly on the other semiconductor layer sequence (H2), and wherein the metal oxide layer is arranged directly between the two donor layers.

15. Structural element according to claim 14, wherein the two donor layers and the metal oxide layer are each formed from an identical transparent conductive material.
